(19) United States
(12) Patent Application Publication
(10) Pub. No.: US 2026/0209939 A1
(43) Pub. Date: Jul. 23, 2026

(54) ATOMIC LAYER DEPOSITION APPARATUS AND METHOD OF DEPOSITING AN ATOMIC LAYER USING THE SAME

(71) Applicant: Samsung Display Co., Ltd., Yongin-si (KR)

(72) Inventors: HYUNGSEOK KIM, Yongin-si (KR); HYELIM KANG, Yongin-si (KR); WOO-SEOK JEON, Yongin-si (KR); SOYEONG JEONG, Yongin-si (KR)

(21) Appl. No.: 19/313,563

(22) Filed: Aug. 28, 2025

(30) Foreign Application Priority Data
Jan. 21, 2025 (KR) 10-2025-0008441

(51) Int. Cl. C23C 16/455; C23C 16/52; H05K 5/02

(52) U.S. Cl. CPC C23C 16/45551; C23C 16/45574; C23C 16/52; H05K 5/02

(57) ABSTRACT

An atomic layer deposition apparatus includes a stage having a substrate thereon and being movable in a first direction and a gas supply module. The gas supply module supplies gas onto the substrate and includes a source gas supply module and a reaction gas supply module, each of which includes nozzles arranged in a second direction crossing the first direction. The source gas supply module includes a first source gas module and a second source gas module. The first and second source gas modules face each other in a third direction different from the first direction and perpendicular to the second direction on a plane defined by the first and second directions.

### CROSS-REFERENCE TO RELATED APPLICATION

The present application claims priority to and the benefit of Korean Patent Application No. 10-2025-0008441, filed on Jan. 21, 2025, the present disclosure of which is incorporated herein in its entirety by reference.

### BACKGROUND

### 1. Field

Aspects of embodiments of the present disclosure relate to an atomic layer deposition apparatus and an atomic layer deposition method.

### 2. Description of the Related Art

Atomic layer deposition (ALD) has been employed as a method for depositing a thin film on a substrate. From among various ALD methods that deposit thin films at the atomic layer level, the spatially separated ALD method utilizes spatially separated dispensing modules to spray a precursor and a reactant onto a substrate and forms a thin film through a chemical reaction between the precursor and the reactant. A purge step using an inert gas is used to remove unreacted precursor and byproducts. This process is repeated to form a thin film having a desired thickness with uniformity and precision.

However, when the thin film is formed in a vertically stacked structure using the spatially separated ALD method, each precursor is injected to the entire substrate in the same sequence. As a result, the uniformity of metal distribution within the oxide film may be lower when compared to sputtering methods. Moreover, in multilayer thin films, the metal composition ratio may vary in different depths, making it difficult to predict the characteristics of a device based on thickness.

### SUMMARY

Embodiments of the present disclosure provide an atomic layer deposition apparatus and an atomic layer deposition method that improves the uniformity of metal distribution in the deposition of multi-component thin films. For example, embodiments of the present disclosure provide an atomic layer deposition apparatus and an atomic layer deposition method that enable simultaneous deposition of multiple types of metal oxides without the need for nozzle sharing by adjusting the arrangement angle of the dispensing module in a spatially separated atomic layer deposition apparatus.

An atomic layer deposition apparatus, according to an embodiment of the present disclosure, includes a stage and a gas supply module. The stage is configured to have a substrate seated thereon and to be movable in a first direction. The gas supply module is configured to supply gas onto the substrate. The gas supply module includes a source gas supply module configured for supplying a source gas and a reaction gas supply module configured for supplying a reaction gas. The source gas supply module and the reaction gas supply module each include nozzles arranged in a second direction crossing the first direction. The source gas supply module includes a first source gas module configured to supply a first source gas and a second source gas module configured to supply a second source gas. The first and second source gas modules are adjacent to each other in a third direction perpendicular to the second direction that is different from the first direction and on a plane defined by the first and second directions.

In an embodiment, the source gas supply module may further include a third source gas module configured to supply a third source gas.

In an embodiment, the third source gas module may be adjacent to the first source gas module with the second source gas module therebetween.

In one embodiment, the reaction gas supply module may be between the first source gas module and the second source gas module.

In an embodiment, the gas supply module may further include a purge gas supply module between the source gas supply module and the reaction gas supply module.

In an embodiment, the gas supply module may further include a vacuum pump between the source gas supply module and the reaction gas supply module.

In an embodiment, the gas supply module may further include a gas supply source and gas supply paths. The gas supply source may be configured to store the source gas and the reaction gas. The gas supply paths may be connected to the gas supply source and may extend in the second direction to supply gas to the source gas nozzles and the reaction gas nozzles.

In an embodiment, the atomic layer deposition apparatus may further include a driving module configured to move the stage in the first direction.

In an embodiment, the driving module may be configured to adjust the tilt angle of the gas supply module so that the nozzles are arranged in the second direction.

In an embodiment, the atomic layer deposition apparatus may further include a control module configured to control a flow rate of the gas supplied from the gas supply module.

In an embodiment, the first and second source gas modules may be alternately arranged along the first direction and may be alternately arranged along the fourth direction, which is perpendicular to the first direction, on a plane defined by the first and second directions.

In an embodiment, the reaction gas supply module may be between the first source gas module and the second source gas module along the first direction and between the first source gas module and the second source gas module along the fourth direction.

In an embodiment, the gas supply module may further include a purge gas module between the first source gas module and the reaction gas supply module along the first direction and between the first source gas module and the reaction gas supply module along the fourth direction. In another embodiment, the gas supply module may further include a purge gas module disposed between the second source gas module and the reaction gas supply module along the first direction and between the second source gas module and the reaction gas supply module along the fourth direction.

An atomic layer deposition method, according to an embodiment of the present disclosure, includes preparing a substrate; and forming an atomic layer on a deposition region on the substrate as the substrate moves in a first direction. The deposition region includes a first region, a second region, and a third region arranged in a second direction perpendicular to the first direction. The forming the atomic layer includes: discharging, during a first time, a first source gas to the first region, a second source gas to the second region, and a third source gas to the third region; discharging, during a second time following the first time, the second source gas to the first region, the third source gas to the second region, and the first source gas to the third region; and discharging, during a third time following the second time, the third source gas to the first region, the first source gas to the second region, and the second source gas to the third region.

In an embodiment, the forming of the atomic layer may further include, between the first time and the second time, discharging a reaction gas to the first to third regions.

In an embodiment, the forming of the atomic layer may further include, between the second time and the third time, discharging a reaction gas to the first to third regions.

In an embodiment, the forming of the atomic layer may further include, between the first time and the second time and prior to the discharging of the reaction gas, discharging a purge gas to the first to third regions. In another embodiment, the forming of the atomic layer may further include, between the second and third time periods and prior to the discharging of the reaction gas, discharging a purge gas onto the first to third regions.

An electronic device, according to an embodiment of the present disclosure, includes a display module, a processor, a memory, and a power module. The display module is configured to output image information based on an image data signal. The processor is configured to execute an application to transfer the image data signal to the display module. The memory is configured to have data information for executing the application stored therein. The power module is configured to supply power to the display module, the processor, and the memory. The display module has a first display region, a second display region, and a third display region. The first display region includes a first deposition layer in which a first material, a second material, and a third material are successively stacked. The second display region includes a second deposition layer in which the second material is at a height corresponding to the first material of the first deposition layer and in which the second material, the third material, and the first material are successively stacked. The third display region includes a third deposition layer in which the third material is at a height corresponding to the first material of the first deposition layer and in which the third material, the first material, and the second material are successively stacked.

In an embodiment, the electronic device may be one of a flat panel display, a curved display, a computer monitor, a medical monitor, a television, a billboard, indoor or outdoor lighting and/or signaling lights, a head-up display, a fully or partially transparent display, a flexible display, a rollable display, a foldable display, a stretchable display, smart glasses, a head-mounted display, a smart watch, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality or augmented reality display, a vehicle instrument cluster, a vehicle center information display (CID), a vehicle head-up display, a room mirror display, a video wall, theater, or stadium screen including multiple displays tiled together, a light therapy device, and a signage.

According to an embodiment of the present disclosure, by adjusting the angle of the dispensing module, multiple types of metal oxides can be deposited in the same scanning step.

Furthermore, according to an embodiment of the present disclosure, because various types of metal oxides are uniformly deposited, the uniformity of metal within the thin film can be improved while maintaining high step coverage.

### BRIEF DESCRIPTION OF THE DRAWINGS

These and/or other aspects and features of the present disclosure will become apparent and more readily appreciated from the following description of embodiments thereof, taken in conjunction with the accompanying drawings, in which:

FIG. 1 is a perspective view of an atomic layer deposition apparatus according to an embodiment of the present disclosure;

FIG. 2 is a cross-sectional view of a head unit of the atomic layer deposition apparatus taken along the line I-I′ in FIG. 1;

FIG. 3 is a cross-sectional view of a head unit of the atomic layer deposition apparatus according to an embodiment of the present disclosure;

FIG. 4 is a diagram illustrating a deposition process according to an embodiment of the present disclosure;

FIG. 5 is an enlarged view of a head unit corresponding to the region SA in FIG. 4;

FIG. 6 is a flow diagram describing steps of a method of depositing an atomic layer by using the atomic layer deposition apparatus according to an embodiment of the present disclosure;

FIG. 7A is a cross-sectional view of a thin film formed on a substrate corresponding to the region AA in FIG. 4;

FIG. 7B is a cross-sectional view of a thin film formed on a substrate corresponding to the region BB in FIG. 4;

FIG. 7C is a cross-sectional view of a thin film formed on a substrate corresponding to the region CC in FIG. 4;

FIG. 8 is a block diagram describing an electronic device manufactured by using the method of depositing an atomic layer according to an embodiment of the present disclosure; and

FIG. 9 illustrates examples of electronic devices incorporating a display device manufactured by using the method of depositing an atomic layer according to an embodiment of the present disclosure.

### DETAILED DESCRIPTION

References will now be made, in detail, to embodiments, examples of which are illustrated in the accompanying drawings. The embodiments may have a variety of forms and permutations, and the present disclosure shall by no means be construed as being limited to the embodiments described herein. Rather, the present disclosure shall be construed to encompass all forms, permutations, equivalents, and substitutes covered by the technical ideas and scope of the present disclosure. Accordingly, embodiments are merely described below, by referring to the figures, to explain aspects and features of the present disclosure.

In the accompanying drawings, the thicknesses, ratios, and dimensions of the elements may not be to exact scale and may be exaggerated for the benefit of effective explanation of the technical features associated with these elements. As such, the present disclosure shall not be restricted to the thicknesses, ratios, dimensions, etc. illustrated in the drawings. The term “and/or” encompasses all possible combinations of the associated elements as defined.

An expression such as “comprising” or “including” is intended to designate a characteristic, a number, a step, an operation, an element, a part or combinations thereof, and shall not be construed to preclude any possibility of presence or addition of one or more other characteristics, numbers, steps, operations, elements, parts or combinations thereof.

Terms such as “first” and “second” may be used in describing various elements, but the above elements shall not be restricted to the above terms. The above terms may be used only to distinguish one element from the other. For instance, the first element may be named the second element, and vice versa, without departing the scope of claims of the present disclosure. Unless clearly used otherwise, any expressions in a singular form may include the meaning of a plural form.

In the present disclosure, first to third directions DR1, DR2, DR3 may be defined to describe an atomic layer deposition apparatus in accordance with certain embodiments. The atomic layer deposition apparatus may deposit an atomic layer on a substrate disposed on a plane defined by the first direction DR1 and the second direction DR2. The third direction DR3 may be defined as the thickness direction of the substrate, and the first to third directions DR1, DR2, DR3 may be mutually orthogonal or intersecting.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

The use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

FIG. 1 is a perspective view of an atomic layer deposition (ALD) apparatus according to an embodiment of the present disclosure. Referring to FIG. 1, an ALD apparatus AD may include a stage ST, a head unit HD, a control module CM, and a driving module. A substrate SS may be disposed on the stage ST.

The stage ST is configured to be moved in a first direction DR1 by the driving module. Accordingly, the substrate SS on which the atomic layer is deposited may be transported in (e.g., moved in) the first direction DR1. As the stage ST moves, atomic layers may be successively deposited on the substrate SS to form a thin film. In an embodiment of the present disclosure, the substrate SS may be a semiconductor substrate or a glass substrate, and a multi-component atomic layer, such as indium gallium zinc oxide (IGZO) layer, may be deposited thereon.

The head unit HD may be disposed on the substrate SS. The head unit HD is configured to supply a precursor and a reactant to form a thin film on the substrate SS. The head unit HD is also configured to supply an inert gas to perform a purge step. The head unit HD may include a gas supply source, a gas supply module, and nozzles. The deposition process through the head unit HD and a detailed configuration of the head unit HD will be described in more detail later. The head unit HD may be configured to allow the precursor and the reactant to be respectively supplied to the deposition region on the substrate SS through separated individual gas supply modules. The ALD apparatus AD may be a spatially separated type.

Referring to FIG. 1, the head unit HD may be tilted at an angle (e.g., a predetermined angle) by the driving module such that the arrangement direction of the nozzles of the head unit HD crosses (e.g., intersects) the first direction DR1 while remaining parallel to a plane defined by the first direction DR1 and a second direction DR2. The tilting operation of the head unit HD will be described in more detail with reference to FIG. 4. The head unit HD may remain fixed and may not move in the first direction DR1, but it is not limited thereto.

The control module CM is configured to manage, perform, and control the overall operation of the ALD apparatus AD. The control module CM is configured to execute (e.g., perform) atomic layer deposition steps and condition control operations. When proceeding with deposition, the control module CM may receive input regarding the start, end, or other aspects of the deposition process and may execute operations for each step. Additionally, the control module CM may transfer information to the head unit HD and the driving module to control the processing conditions. The control module CM may also control the head unit HD and the driving module. For example, the control module CM may receive input information for tilting the head unit HD and may transfer the input information to the driving module.

The control module CM may include a processor, a memory, and a storage. The deposition process and condition control operations performed by the control module CM may be implemented in firmware or software. For example, the firmware may be stored in the storage and loaded into the memory when executed. The processor may be configured to execute the firmware that is loaded in the memory. However, the control module CM is not limited thereto and, in some embodiments, may be implemented with dedicated hardware. For example, the control module CM may be implemented with dedicated logic circuits, such as a field programmable gate array (FPGA) or application-specific integrated circuit (ASIC), configured for performing ALD operations. The control module CM may also include a display unit, such as a monitor or a tablet, for displaying the progress or error information related to the deposition process.

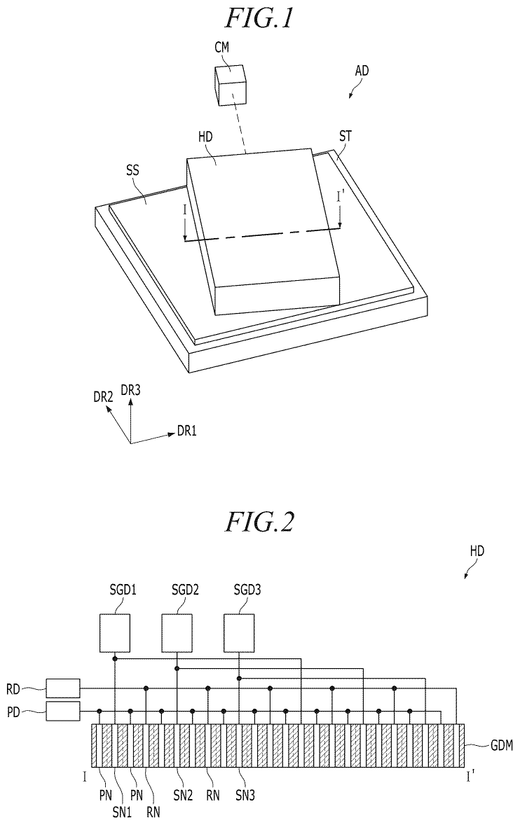

FIG. 2 is a cross-sectional view of the head unit of the ALD apparatus taken along the line I-I′ in FIG. 1. The head unit HD may include first to third source gas supplies SGD1, SGD2, SGD3, a reaction gas supply RD, a purge gas supply PD, a gas supply module GDM, and a plurality of nozzles SN1, SN2, SN3, RN, PN. Because the ALD apparatus AD (see, e.g., FIG. 1) is the spatially separated type, the gas supply module GDM of the head unit HD may include partitions configured such that each fluid is spatially separated and independently supplied onto the substrate SS (see, e.g., FIG. 1). The head unit HD may also include gas supply paths configured to allow gas to be supplied from the plurality of gas supplies SGD1, SGD2, SGD3, RD, PD to the corresponding nozzles SN1, SN2, SN3, RN, PN.

The head unit HD is configured to supply a source gas as a precursor, a reaction gas as a reactant, and a purge gas as an inert fluid (e.g., an inert gas) to respectively supply the source gas and reaction gas to the deposition region of the substrate SS. The source gases may be stored in the first to third source gas supplies SGD1, SGD2, SGD3 and transferred through the gas supply paths to the respective source gas nozzles SN1, SN2, SN3, which supply the source gases onto the substrate SS. To deposit multi-component thin films, the head unit HD may include a first source gas supply SGD1, a second source gas supply SGD2, and a third source gas supply SGD3. However, the number of source gas supplies is not limited thereto.

The reaction gas may be stored in the reaction gas supply RD, transferred to the reaction gas nozzle RN through a gas supply path, and supplied onto the substrate SS. Moreover, the purge gas may be supplied to remove unreacted precursor and byproducts after the source gas and the reaction gas are supplied. The purge gas may be stored in the purge gas supply PD, transferred to the purge gas nozzle PN through a gas supply path, and supplied onto the substrate SS.

In an embodiment, the first source gas supply SGD1 may be configured to store indium oxide (In₂O₃), and the first source gas nozzles SN1 may be configured to supply indium oxide (In₂O₃). The second source gas supply SGD2 may be configured to store gallium oxide (Ga₂O₃), and the second source gas nozzles SN2 may be configured to supply gallium oxide (Ga₂O₃). The third source gas supply SGD3 may be configured to store zinc oxide (ZnO), and the third source gas nozzles SN3 may be configured to supply zinc oxide (ZnO). The reaction gas supply RD may be configured to store oxygen (O₂) plasma and to supply oxygen (O₂) plasma through the reaction gas nozzles RN. The purge gas supply PD may be configured to store nitrogen (N₂) and to supply nitrogen (N₂) through the purge gas nozzles PN to remove unused (or unnecessary) residual materials or byproducts without chemically reacting with other materials.

Accordingly, indium gallium zinc oxide (IGZO) may be deposited on the substrate SS. A multi-component metal oxide laminate layer, such as the IGZO layer, deposited by the ALD apparatus may be applied as an active layer of a display device. The multi-component metal oxide laminate layer may be used as a semiconductor channel layer of a thin-film transistor (TFT) in a display device. However, application examples of the multi-component metal oxide laminate layer are not limited thereto.

As illustrated in FIG. 2, the source gas nozzles SN1, SN2, SN3, the reaction gas nozzles RN, and the purge gas nozzles PN may be spatially separated from each other by partitions. The source gas nozzles SN1, SN2, SN3 may be arranged sequentially and repeatedly along the direction in which the gas supply paths are disposed. Moreover, the reaction gas nozzles RN may be disposed between the first and second source gas nozzles SN1, SN2, between the second and third source gas nozzles SN2, SN3, and between the third and first source gas nozzles SN3, SN1. The purge gas nozzles PN may be disposed between any one of the source gas nozzles SN1, SN2, SN3 and the reaction gas nozzle RN. The gas supply paths may be connected to the respective gas supplies SGD1, SGD2, SGD3, RD, PD and may extend in the same direction in which the corresponding nozzles are arranged, but the configuration is not limited thereto.

Vacuum pumps may be provided on either side of each nozzle. The vacuum pumps may be configured to maintain the internal pressure of the ALD apparatus at a vacuum level and to exhaust unreacted materials, thereby enabling a uniform and efficient deposition process. Moreover, each of the nozzles may include a valve configured to control the flow rate of the fluid. The valve may be controlled by the control module CM (see, e.g., FIG. 1). Accordingly, by opening and closing the valves corresponding to the source gas nozzles SN1, SN2, SN3, the flow rates of the first to third source gases may be regulated, thereby adjusting the composition ratio.

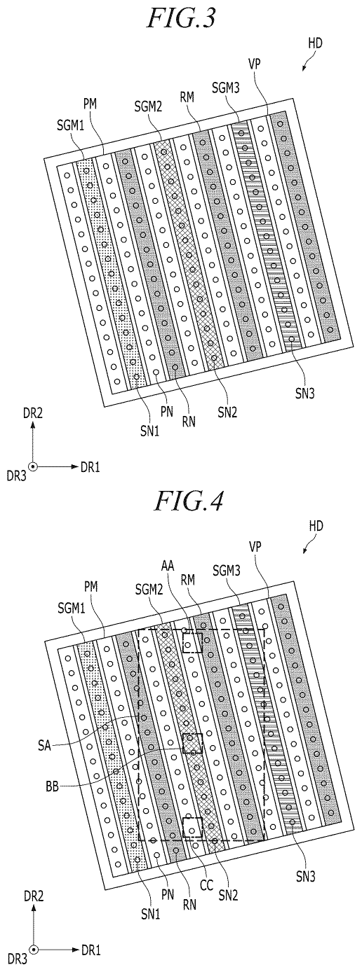

FIG. 3 is a cross-sectional view illustrating the head unit of the ALD apparatus according to an embodiment of the present disclosure. The head unit HD may include a gas supply module, a plurality of nozzles corresponding to the gas supply module, and a vacuum pump VP. The gas supply module may include first to third source gas modules SGM1, SGM2, SGM3, a reaction gas supply module RM, and a purge gas supply module PM. Accordingly, the head unit HD may include a plurality of nozzles SN1, SN2, SN3, RN, PN corresponding to the respective modules. The vacuum pump VP may be provided on both sides of the gas supply module.

Referring to FIG. 3, the head unit HD is tilted at an angle (e.g., a predetermined angle) on a plane defined by the first direction DR1 and the second direction DR2, the gas supply module may include nozzles arranged in a direction crossing (e.g., intersecting) the first direction DR1, which is the direction in which the substrate SS (see, e.g., FIG. 1) moves. In addition, the first to third source gas modules SGM1, SGM2, SGM3, the reaction gas supply module RM, and the purge gas supply module PM may be sequentially and repeatedly arranged in the direction crossing the first direction DR1.

In an embodiment, the first and second source gas modules SGM1, SGM2 may face each other (e.g., may be adjacent to each other) in a direction perpendicular to the arrangement direction of the first source gas nozzles SN1 on the plane defined by the first direction DR1 and the second direction DR2. Similarly, the second and third source gas modules SGM2, SGM3 may face each other (e.g., may be adjacent to each other) in a direction perpendicular to the arrangement direction of the second source gas nozzles SN2 on the plane defined by the first direction DR1 and the second direction DR2, and the third and first source gas modules SGM3, SGM1 may face each other (e.g., may be adjacent to each other) in a direction perpendicular to the arrangement direction of the third source gas nozzles SN3 on the plane defined by the first direction DR1 and the second direction DR2.

The arrangement sequence of the first to third source gas modules SGM1, SGM2, SGM3, the reaction gas supply module RM, and the purge gas supply module PM may be, but is not limited to, the same as the sequence of the nozzles SN1, SN2, SN3, RN, PN as described above with respect to FIG. 2. Additionally, one or more of the source gas modules SGM1, SGM2, SGM3 may be added to the head unit HD to increase the supply ratio of a specific source gas.

Because the first to third source gas modules SGM1, SGM2, SGM3, the reaction gas supply module RM, and the purge gas supply module PM are arranged in a direction crossing (e.g., intersecting) the first direction DR1, the metal composition distribution on the substrate may be controlled as if a cocktail (or mixed) precursor is used, even without sharing the individual nozzles. Moreover, the composition ratio and deposition rate of each element may be controlled by adjusting the tilt angle of the head unit HD or the spacing between the nozzles. The composition ratio and deposition rate may also be controlled by selectively opening and closing the individual nozzles in the head unit HD. For example, the tilt angle of the head unit HD may be greater than 0° and smaller than about 90°.

FIG. 4 is a diagram illustrating a deposition process according to an embodiment of the present disclosure. During the deposition process of the ALD apparatus, the head unit HD may be placed on the substrate. Referring to FIG. 4, region SA corresponds to a region of the substrate and may be defined as the region in which an atomic layer is deposited. As the substrate moves in the first direction DR1, the first to third source gases and the reaction gas may be supplied to the region SA, thereby enabling deposition of (e.g., formation of) an atomic layer. Moreover, the region SA may have first to third regions AA, BB, CC, which are arranged along the second direction DR2 perpendicular to the first direction DR1.

Because the head unit HD is tilted to cross (e.g., intersect) the first direction DR1 on the plane defined by the first direction DR1 and the second direction DR2, the type of gas supplied to each of the regions AA, BB, CC at the same point in time may differ. For example, when the tilt angle of the head unit HD is 0°, the same type of gas may be supplied concurrently (or simultaneously) to all of the regions AA, BB, CC, but when the tilt angle is greater than 0° and smaller than about 90°, different types of gas may be supplied concurrently (or simultaneously) to the respective regions AA, BB, CC. As a result, the uniformity of the metal distribution in the thin film may be improved, and the composition distribution of the metal may be controlled.

FIG. 5 is an enlarged view of the head unit corresponding to the region SA shown in FIG. 4. Because the configuration of the nozzles in the head unit corresponding to the region SA changes as the substrate moves in the first direction DR1, FIG. 5 may be understood as illustrating the head unit corresponding to the region SA at a particular point in time during the deposition process. Referring to FIG. 5, as described in FIG. 4, the head unit is tilted to cross (e.g., intersect) the first direction DR1, and the nozzles SN1, SN2, SN3, RN, PN of the head unit corresponding to the region SA may be alternately arranged along both the first direction DR1 and the second direction DR2. For example, FIG. 5 may be understood to be an enlarged view of the head unit when the tilt angle is 45°.

Referring to FIG. 5, each of the first to third source gas nozzles SN1, SN2, SN3 may be arranged in an alternating manner along the first direction DR1 and may be alternately arranged along the second direction DR2. Moreover, each of the reaction gas nozzles RN may be disposed between the first and second source gas nozzles SN1, SN2, between the second and third source gas nozzles SN2, SN3, and between the third and first source gas nozzles SN3, SN1. Each of the purge gas nozzles PN may be disposed between the source gas nozzles SN1, SN2, SN3 and the reaction gas nozzles RN along both the first and second directions DR1, DR2. Nonetheless, it shall be appreciated that the arrangement sequence of the nozzles SN1, SN2, SN3, RN, PN is not limited to the illustrated configuration.

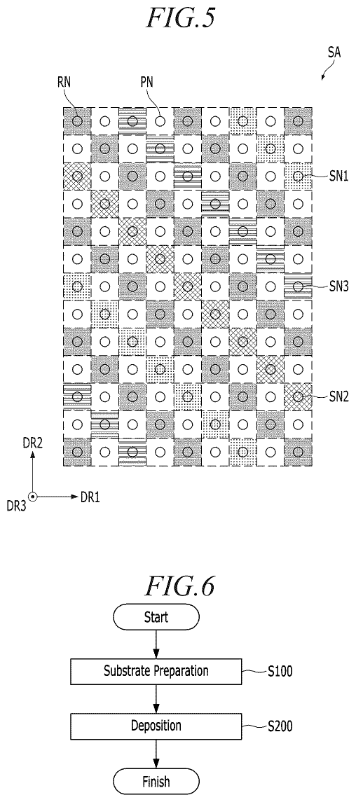

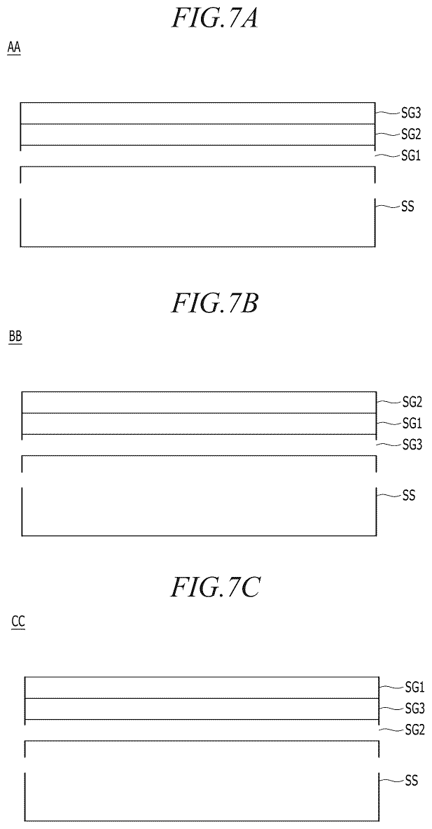

FIG. 6 is a flow diagram describing steps of a method of depositing an atomic layer by using the ALD apparatus according to an embodiment of the present disclosure. FIGS. 7A to 7C are cross-sectional views of thin films on a substrate, respectively corresponding to the regions AA, BB, and CC shown in FIG. 4, as formed by the method of depositing an atomic layer according to an embodiment of the present disclosure. The method described in FIG. 6 will be further described with reference to FIG. 4 and FIGS. 7A to 7C.

Referring to FIG. 6, the atomic layer deposition method may include a substrate preparation step (S100) and a deposition step (S200).

In the substrate preparation step (S100), a substrate SS (see, e.g., FIG. 1) may be prepared on a stage ST (see, e.g., FIG. 1). The prepared substrate may be moved in a first direction during the deposition step (S200), and a deposition region of (or on) the substrate may include first to third regions arranged in a second direction that is perpendicular to the first direction. The first region may correspond to the region AA in FIG. 4, the second region to the region BB, and the third region to the region CC.

In the deposition step (S200), an atomic layer may be formed in the deposition region of the substrate moving in the first direction. The deposition step (S200) may include first to third stages in which different operations are performed at (or during) a first time, a second time, and a third time.

In the first stage, during the first time, a first source gas SG1 (see, e.g., FIGS. 7A to 7C) may be discharged to the first region AA (see, e.g., FIGS. 4 and 7A), a third source gas SG3 (see, e.g., FIGS. 7A to 7C) may be discharged to the second region BB (see, e.g., FIGS. 4 and 7B), and a second source gas SG2 (see, e.g., FIGS. 7A to 7C) may be discharged to the third region CC (see FIGS. 4 and 7C).

In the second stage, during the second time following (or after) the first time, the second source gas SG2 may be discharged to the first region AA, the first source gas SG1 to the second region BB, and the third source gas SG3 to the third region CC.

In the third stage, during the third time after (or following) the second time, the third source gas SG3 may be discharged to the first region AA, the second source gas SG2 to the second region BB, and the first source gas SG1 to the third region CC.

For example, the first source gas SG1 may be indium oxide (In₂O₃), the second source gas SG2 may be gallium oxide (Ga₂O₃), and the third source gas SG3 may be zinc oxide (ZnO). Accordingly, referring to FIGS. 7A to 7C, the order in which the source gases are supplied to the substrate SS may differ across the first to third regions AA, BB, CC. In other words, different stacking structures may be formed in the respective regions AA, BB, CC.

Referring to the above description, the types of source gases supplied over time to the first to third regions AA, BB, CC may be as shown in Table 1 below.

TABLE 1

| | First Time | Second Time | Third Time |
|---|---|---|---|
| First | First Source Gas | Second Source Gas | Third Source Gas |
| Region | | | |
| Second | Third Source Gas | First Source Gas | Second Source Gas |
| Region | | | |
| Third | Second Source Gas | Third Source Gas | First Source Gas |
| Region | | | |

The deposition step (S200) may further include a reaction gas discharge step of discharging a reaction gas onto the first to third regions between the first and second times and between the second and third times. For example, the reaction gas may be oxygen (O₂) plasma.

The deposition step (S200) may further include a first purge gas discharge step of discharging a purge gas onto the first to third regions prior to the reaction gas discharge step between the first and second times and between the second and third times. Additionally, the deposition step (S200) may further include a second purge gas discharge step of discharging a purge gas onto the first to third regions after the reaction gas discharge step between the first and second times and between the second and third times. For example, the purge gas may be nitrogen (N₂).

The deposition step (S200) may further include a step of exhausting unreacted source gases, reaction gases, byproducts, and other unused (or unnecessary) gases through vacuum pumps VP (see, e.g., FIG. 4) after the first to third stages, the reaction gas discharge step, the first purge gas discharge step, and the second purge gas discharge step.

The first to third stages may be sequentially repeated, and accordingly, the first to third source gases SG1, SG2, SG3 may be deposited in a periodically repeated stacking order that corresponds to the spacing of the nozzles in the ALD apparatus. Because the order of source gas deposition varies across the first to third regions AA, BB, CC arranged in the second direction, a multi-component thin film having a uniform metal distribution—similar to that formed by sputtering—can be deposited (e.g., formed). Therefore, the method of depositing an atomic layer according to an embodiment of the present disclosure may achieve high uniformity of metal distribution in the thin film, similar to sputtering techniques, while maintaining the advantages of atomic layer deposition, such as high step coverage and excellent coverage over complex thin-film patterns.

The atomic layer deposition method, according to an embodiment of the present disclosure, may be applied to various electronic devices. An electronic device according to an embodiment of the present disclosure may include a display device manufactured by using the atomic layer deposition method described above and may further include modules or devices having other additional functions in addition to the display device.

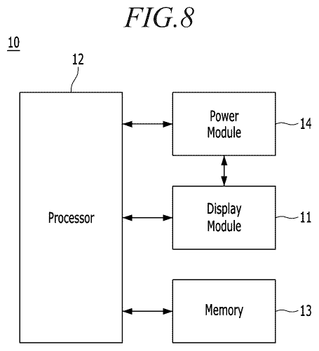

FIG. 8 is a block diagram describing an electronic device manufactured by using the atomic layer deposition method according to an embodiment of the present disclosure. Referring to FIG. 8, an electronic device 10, according to an embodiment, may include a display module 11, a processor 12, a memory 13, and a power module 14.

The display module 11 may have a first display region, a second display region, and a third display region. The first display region may include a first deposition layer in which a first material, a second material, and a third material are successively stacked. The second display region may include a second deposition layer in which the second material is disposed at a height corresponding to the first material of the first deposition layer and in which the second material, the third material, and the first material are successively stacked. The third display region may include a third deposition layer in which the third material is disposed at a height corresponding to the first material of the first deposition layer and in which the third material, the first material, and the second material are successively stacked.

In an embodiment, the first material may be indium oxide (In₂O₃), the second material may be gallium oxide (Ga₂O₃), and the material may be zinc oxide (ZnO). Accordingly, the first to third deposition layers may be (or may form) a multi-component metal oxide laminate layer, such as indium gallium zinc oxide (IGZO) layer.

The processor 12 may include at least one of a central processing unit (CPU), an application processor (AP), a graphic processing unit (GPU), a communication processor (CP), an image signal processor (ISP), and a controller.

Stored in the memory 13 may be data information for the operation of the processor 12 or the display module 11. When the processor 12 executes an application stored in the memory 13, an image data signal and/or an input control signal may be transferred to the display module 11, which may then process the received signal/signals and output (e.g., emit) image information through a display screen.

The power module 14 may include a power supply module, such as a power adapter or a battery device, and a power conversion module configured to convert the power supplied by the power supply module to generate power for the operation of the electronic device 10.

At least one of the components of the electronic device 10 described above may be included in the display device. Moreover, some of the individual modules functionally included in a single module may be included in the display device, while others may be separately provided from the display device. For example, the display device may include the display module 11, whereas the processor 12, the memory 13, and the power module 14 may be provided as separate components within the electronic device 10 rather than as part of the display device.

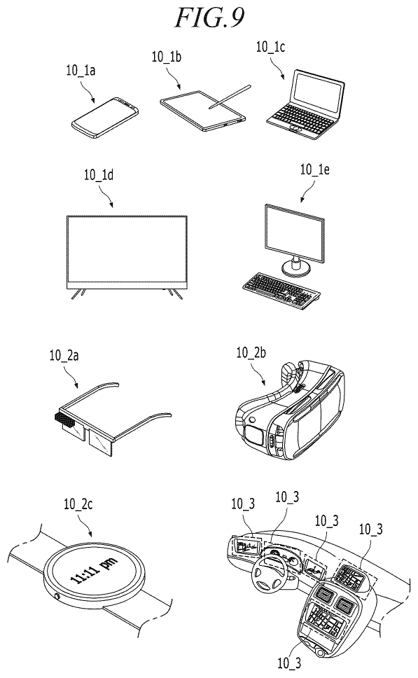

FIG. 9 illustrates examples of electronic devices incorporating a display device manufactured by using the method of depositing an atomic layer according to an embodiment of the present disclosure. Referring to FIG. 9, various electronic devices to which the display device according to the embodiments is applied may include not only image-displaying electronic devices, such as a smartphone 10_1a, a tablet PC 10_1b, a laptop computer 10_1c, a TV set 10_1d, and a desktop monitor 10_1e, but also wearable electronic devices including a display module, such as smart glasses 10_2a, a head-mounted display device 10_2b, and a smartwatch 10_2c. The display device may also be applied to automotive electronic devices 10_3 including a display module, such as a vehicle instrument panel, a center fascia, a dashboard-integrated center information display (CID), and a room mirror display. Embodiments of the present disclosure have been described herein, but these are merely examples and are not intended to limit the present disclosure. Those skilled in the art to which the present disclosure pertains may make various modifications and changes to the embodiments by adding, changing, deleting, or adding certain elements, without departing from the scope of the technical ideas of the present disclosure as set forth in the claims and their equivalents, and such modifications and changes should also be regarded as being within the scope of the present disclosure.

What is claimed is:

1. An atomic layer deposition apparatus comprising:
a stage configured to have a substrate seated thereon and to be moved in a first direction; and
a gas supply module configured to supply gas onto the substrate, the gas supply module comprising:
a source gas supply module configured to supply a source gas; and
a reaction gas supply module configured to supply a reaction gas,
wherein each of the source gas supply module and the reaction gas supply module comprises nozzles arranged in a second direction crossing the first direction,
wherein the source gas supply module comprises:
a first source gas module configured to supply a first source gas; and
a second source gas module configured to supply a second source gas, and
wherein the first and second source gas modules are adjacent to each other in a third direction that is perpendicular to the second direction on a plane defined by the first and second directions, the third direction being different from the first direction.

2. The atomic layer deposition apparatus of claim 1, wherein the source gas supply module further comprises a third source gas module configured to supply a third source gas.

3. The atomic layer deposition apparatus of claim 2, wherein the third source gas module is adjacent to the first source gas module with the second source gas module therebetween.

4. The atomic layer deposition apparatus of claim 1, wherein the reaction gas supply module is between the first source gas module and the second source gas module.

5. The atomic layer deposition apparatus of claim 4, wherein the gas supply module further comprises a purge gas supply module between the source gas supply module and the reaction gas supply module.

6. The atomic layer deposition apparatus of claim 4, wherein the gas supply module further comprises a vacuum pump between the source gas supply module and the reaction gas supply module.

7. The atomic layer deposition apparatus of claim 1, wherein the gas supply module further comprises:
a gas supply source configured to store the source gas and the reaction gas; and
gas supply paths connected to the gas supply source and extending in the second direction to supply gas to the source gas nozzles and the reaction gas nozzles.

8. The atomic layer deposition apparatus of claim 1, further comprising a driving module configured to move the stage in the first direction.

9. The atomic layer deposition apparatus of claim 8, wherein the driving module is configured to adjust a tilt angle of the gas supply module such that the nozzles are arranged in the second direction.

10. The atomic layer deposition apparatus of claim 1, further comprising a control module configured to control a flow rate of the gas supplied from the gas supply module.

11. The atomic layer deposition apparatus of claim 1, wherein the first source gas module and the second source gas module are alternately arranged along the first direction and are alternately arranged along a fourth direction that is perpendicular to the first direction on a plane defined by the first and second directions.

12. The atomic layer deposition apparatus of claim 11, wherein the reaction gas supply module is between the first source gas module and the second source gas module along the first direction, and
wherein the reaction gas supply module is between the first source gas module and the second source gas module along the fourth direction.

13. The atomic layer deposition apparatus of claim 12, wherein the gas supply module further comprises a purge gas module between the first source gas module and the reaction gas supply module along the first direction and is between the first source gas module and the reaction gas supply module along the fourth direction.

14. The atomic layer deposition apparatus of claim 12, wherein the gas supply module further comprises a purge gas module between the second source gas module and the reaction gas supply module along the first direction and is between the second source gas module and the reaction gas supply module along the fourth direction.

15. An atomic layer deposition method comprising:
preparing a substrate; and
forming an atomic layer on a deposition region on the substrate as the substrate moves in a first direction,
wherein the deposition region includes a first region, a second region, and a third region arranged in a second direction perpendicular to the first direction,
wherein the forming the atomic layer comprises:
discharging, during a first time, a first source gas to the first region, a second source gas to the second region, and a third source gas to the third region;
discharging, during a second time following the first time, the second source gas to the first region, the third source gas to the second region, and the first source gas to the third region; and
discharging, during a third time following the second time, the third source gas to the first region, the first source gas to the second region, and the second source gas to the third region.

16. The atomic layer deposition method of claim 15, wherein the forming of the atomic layer further comprises, between the first time and the second time, discharging a reaction gas to the first to third regions.

17. The atomic layer deposition method of claim 15, wherein the forming of the atomic layer further comprises, between the second time and the third time, discharging a reaction gas to the first to third regions.

18. The atomic layer deposition method of claim 16, wherein the forming of the atomic layer further comprises, between the first time and the second time and between the second time and the third time, discharging a purge gas to the first to third regions.

19. An electronic device comprising:
a display module configured to output image information based on an image data signal;
a processor configured to execute an application to transfer the image data signal to the display module;
a memory in which data information for executing the application is stored; and
a power module configured to supply power to the display module, the processor, and the memory,
wherein the display module has a first display region, a second display region, and a third display region,
wherein the first display region comprises a first deposition layer in which a first material, a second material, and a third material are sequentially stacked,
wherein the second display region comprises a second deposition layer in which the second material is at a height corresponding to the position of the first material in the first deposition layer, and the second material, the third material, and the first material are sequentially stacked, and
wherein the third display region comprises a third deposition layer in which the third material is at a height corresponding to the position of the first material in the first deposition layer, and the third material, the first material, and the second material are sequentially stacked.

20. The electronic device of claim 19, wherein the electronic device is one of a flat panel display, a curved display, a computer monitor, a medical monitor, a television, a billboard, indoor or outdoor lighting and/or signaling lights, a head-up display, a fully or partially transparent display, a flexible display, a rollable display, a foldable display, a stretchable display, smart glasses, a head-mounted display, a smart watch, a laser printer, a telephone, a mobile phone, a tablet, a phablet, a personal digital assistant (PDA), a wearable device, a laptop computer, a digital camera, a camcorder, a viewfinder, a micro display, a 3D display, a virtual reality or augmented reality display, a vehicle instrument cluster, a vehicle center information display (CID), a vehicle head-up display, a room mirror display, a video wall, theater, or stadium screen including multiple displays tiled together, a light therapy device, and a signage.
